(19) United States
(12) Patent Application Publication
(10) Pub. No.: US 2021/0027994 A1
(43) Pub. Date: Jan. 28, 2021

(54) SHUTTER MECHANISM AND SUBSTRATE PROCESSING APPARATUS

(71) Applicant: TOKYO ELECTRON LIMITED, Tokyo (JP)

(72) Inventors: Suguru MOTEGI, Miyagi (JP); Nobutaka SASAKI, Miyagi (JP)

(73) Assignee: TOKYO ELECTRON LIMITED, Tokyo (JP)

(21) Appl. No.: 16/933,400

(22) Filed: Jul. 20, 2020

(30) Foreign Application Priority Data
Jul. 26, 2019 (JP) 2019-138077

(51) Int. Cl. H01J 37/32; H01L 21/677

(52) U.S. Cl. CPC H01J 37/32513; H01J 2237/334; H01J 2237/166; H01L 21/67742

(57) ABSTRACT

A shutter mechanism for opening and closing an opening of a cylindrical chamber of a substrate processing apparatus is provided. The shutter mechanism includes a valve body having a circumferential length of at least half of an inner circumference of the chamber, and two or more elevating mechanisms connected to a lower portion of the valve body and configured to vertically move the valve body.

### CROSS-REFERENCE TO RELATED APPLICATIONS

This application claims priority to Japanese Patent Application No. 2019-138077, filed on Jul. 26, 2019, the entire contents of which are incorporated herein by reference.

### TECHNICAL FIELD

The present disclosure relates to a shutter mechanism and a substrate processing apparatus.

### BACKGROUND

Conventionally, there is known a plasma processing apparatus that performs desired plasma processing on a wafer that is used as a processing target substrate for a semiconductor device. The plasma processing apparatus includes a chamber that accommodates therein, e.g., a wafer. A substrate support that mounts thereon the wafer and serves as a lower electrode, and an upper electrode facing the substrate support are disposed in the chamber. A radio frequency power supply is connected to at least one of the substrate support and the upper electrode, and at least one of the substrate support and the upper electrode applies a radio frequency power to an inner space of the processing chamber. In the plasma processing apparatus, a processing gas supplied into the inner space of the processing chamber is turned into plasma by the radio frequency power to generate ions and the like. Then, the generated ions and the like are guided to the wafer to perform desired plasma processing such as etching on the wafer (see, e.g., Japanese Patent Application Publication No. 2015-126197).

The present disclosure provides a shutter mechanism capable of enlarging an opening and pressing a valve body with a uniform force, and a substrate processing apparatus including the shutter mechanism.

### SUMMARY

In accordance with an aspect of the present disclosure, there is provided a shutter mechanism for opening and closing an opening of a cylindrical chamber of a substrate processing apparatus, including: a valve body having a circumferential length of at least half of an inner circumference of the chamber; and two or more elevating mechanisms connected to a lower portion of the valve body and configured to vertically move the valve body.

### BRIEF DESCRIPTION OF THE DRAWINGS

The objects and features of the present disclosure will become apparent from the following description of embodiments, given in conjunction with the accompanying drawings, in which:

FIG. 1 shows an example of a substrate processing apparatus according to an embodiment of the present disclosure;

FIG. 2 is a partially enlarged view showing an example of a cross section of a shutter mechanism according to the embodiment;

FIG. 3 shows an example of an external appearance of the shutter mechanism according to the embodiment; and

FIGS. 4 to 6 show an example of an external appearance of a chamber according to the embodiment.

### DETAILED DESCRIPTION

Hereinafter, embodiments of a shutter mechanism and a substrate processing apparatus of the present disclosure will be described in detail with reference to the accompanying drawings. However, it should be noted that the following embodiments are not intended to limit the present disclosure.

In a plasma processing apparatus, at a sidewall of a chamber, an opening for loading and unloading a semiconductor wafer is formed, and a gate valve for opening and closing the opening is provided. The semiconductor wafer is loaded into and unloaded from the chamber by opening and closing the opening with the gate valve. In the chamber, a deposition shield that prevents etching by-products (deposits) from being adhered to an inner wall of the chamber is disposed along the inner wall of the chamber, and the deposition shield also has an opening at a position corresponding to the opening of the chamber.

Since the gate valve is disposed outside the chamber (on a transfer chamber side), a space where an opening is opened toward the transfer chamber is formed at the sidewall of the chamber. When the plasma generated in the chamber diffuses to the space of the opening, the uniformity of the plasma may decrease or a sealing member of the gate valve may be deteriorated by the plasma. Therefore, the opening of the deposition shield and the opening of the chamber are configured to be blocked by a shutter. The shutter is opened and closed by a driving unit disposed below the openings.

Recently, it has been required to transfer parts provided in the chamber that are greater in size than an outer diameter of the wafer through the opening of the chamber, and also has been required to enlarge the opening and scale up a valve body of the shutter. However, if the valve body of the shutter is scaled up in size, the contact area between the valve body and the deposition shield against which the valve body is pressed is increased. In that case, it is difficult to ensure sufficient conduction between the valve body and the deposition shield. Therefore, it is desired to enlarge the opening and to press the valve body with a uniform force.

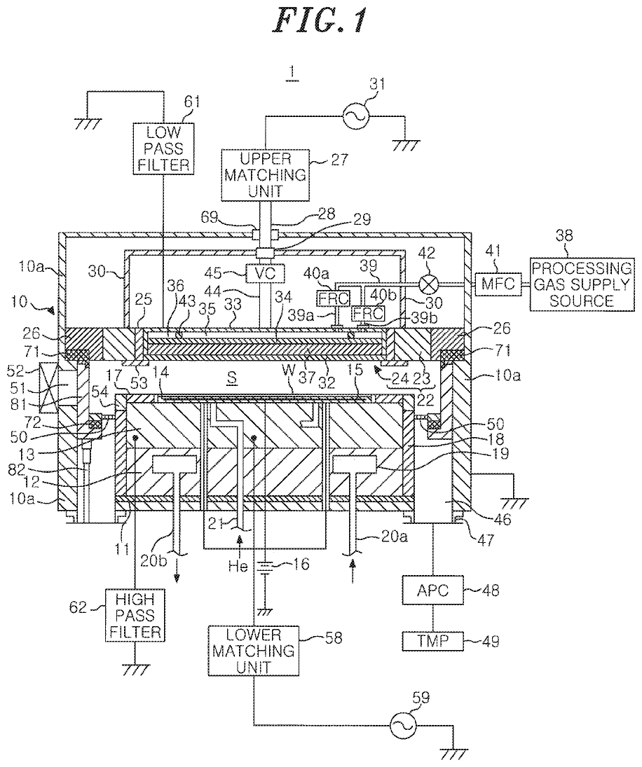

(Configuration of the substrate processing apparatus) FIG. 1 shows an example of a substrate processing apparatus according to an embodiment of the present disclosure. In the following description, a case where the substrate processing apparatus is configured as a plasma processing apparatus will be described as an example. However, the present disclosure is not limited thereto and may be applicable to any substrate processing apparatus having a shutter member.

In FIG. 1, a plasma processing apparatus 1 is configured as a capacitively coupled parallel plate plasma etching apparatus. The plasma processing apparatus 1 includes a cylindrical chamber (processing chamber) 10 made of, e.g., aluminum having an alumite-treated (anodically oxidized) surface. The chamber 10 is frame-grounded. However, the plasma processing apparatus 1 is not limited to the capacitively coupled parallel plate plasma etching apparatus and may be any plasma processing apparatus using inductively coupled plasma (ICP), microwave plasma, magnetron plasma, or the like.

A columnar susceptor support 12 is disposed on a bottom portion of the chamber 10 with an insulating plate 11 made of ceramic or the like provided therebetween. A conductive susceptor 13 made of, e.g., aluminum, is disposed on the susceptor support 12. The susceptor 13 serves as a lower electrode and places thereon an etching target substrate, e.g., a wafer W that is a semiconductor wafer.

An electrostatic chuck (ESC) 14 for attracting and holding the wafer W using an electrostatic attractive force is disposed on an upper surface of the susceptor 13. The electrostatic chuck 14 includes an electrode plate 15 made of a conductive film and two insulating layers made of a dielectric material, e.g., Y₂O₃, Al₂O₃, AlN, or the like. The electrode plate 15 is embedded between the two insulating layers. A DC power supply 16 is electrically connected to the electrode plate 15 through a connection terminal. The wafer W is attracted and held on the electrostatic chuck 14 by a Coulomb force or a Johnsen-Rahbek force generated by a DC voltage applied by the DC power supply 16.

A plurality of pusher pins, e.g., three pusher pins, as lift pins capable of protruding beyond and retracting below the upper surface of the electrostatic chuck 14, is disposed at a portion of the upper surface of the electrostatic chuck 14 where the wafer W is attracted and held. These pusher pins are connected to a motor (not shown) through ball screws (not shown) and protrude beyond and retract below the upper surface of the electrostatic chuck 14 by linear motion converted from rotational motion of the motor by the ball screws. Accordingly, the pusher pins penetrate through the electrostatic chuck 14 and the susceptor 13 and move vertically therein. In the case of attracting and holding the wafer W on the electrostatic chuck 14 for performing an etching on the wafer W, the pusher pins are accommodated in the electrostatic chuck 14. In the case of unloading the etched wafer W from a plasma generation space S, the pusher pins protrude from the electrostatic chuck 14 to separate the wafer W from the electrostatic chuck 14 and lift the wafer W upward. Further, an edge ring 17 made of, e.g., silicon (Si), is disposed on a peripheral portion of the upper surface of the susceptor 13 to improve etching uniformity. A cover ring 54 is disposed to surround the edge ring 17 to protect a side portion of the edge ring 17. Further, the side surfaces of the susceptor 13 and the susceptor support 12 are covered by a cylindrical member 18 made of, e.g., quartz (SiO₂).

A coolant chamber 19 extending in, e.g., a circumferential direction, is formed in the susceptor support 12. A coolant, e.g., cooling water, having a predetermined temperature is supplied from an external chiller unit (not shown) and circulated in the coolant chamber 19 through lines 20a and 20b. In the coolant chamber 19, a processing temperature of the wafer W on the susceptor 13 is controlled by adjusting the temperature of the coolant.

Further, by supplying a heat transfer gas, e.g., helium (He) gas, from a heat transfer gas supply mechanism (not shown) to a gap between the upper surface of the electrostatic chuck 14 and the rear surface of the wafer W through a gas supply line 21, the heat transfer between the wafer W and the susceptor 13 is efficiently and uniformly controlled.

An upper electrode 22 is disposed above the susceptor 13 to be opposite to the susceptor 13 in parallel therewith. Here, a space formed between the susceptor 13 and the upper electrode 22 functions as a plasma generation space S (inner space of the processing chamber). The upper electrode 22 includes an annular or a donut-shaped outer upper electrode 23 that is opposite to the susceptor 13 with a predetermined distance therebetween, and a disc-shaped inner upper electrode 24 disposed at a radially inner side of the outer upper electrode 23 while being electrically insulated from the outer upper electrode 23. Further, the outer upper electrode 23 functions as a main electrode for the plasma generation and the inner upper electrode 24 functions as a secondary electrode for the plasma generation.

An annular gap of, e.g., 0.25 mm to 2.0 mm, is formed between the outer upper electrode 23 and the inner upper electrode 24. A dielectric 25 made of, e.g., quartz, is disposed in the gap. Alternatively, a ceramic body may be disposed in the gap, instead of the dielectric 25 made of quartz. With the dielectric 25 between the outer upper electrode 23 and the inner upper electrode 24, a capacitor is formed. A capacitance Cl of the capacitor is selected or adjusted to a desired value depending on a size of the gap and a relative permittivity of the dielectric 25. Further, an annular insulating shield member 26 made of, e.g., alumina (Al₂O₃) or yttria (Y₂O₃), is hermetically disposed between the outer upper electrode 23 and a sidewall of the chamber 10.

The outer upper electrode 23 is preferably made of a semiconductor or a conductor of low resistance with low Joule heating, e.g., silicon. The outer upper electrode 23 is electrically connected to an upper radio frequency power supply 31 through an upper matching unit 27, an upper power feed rod 28, a connector 29, and a power feeder 30. The upper matching unit 27 serves to match a load impedance with an internal impedance (or output impedance) of the upper radio frequency power supply 31. The upper matching unit 27 controls the load impedance and the output impedance of the upper radio frequency power supply 31 to be apparently matched with each other when plasma is generated in the chamber 10. Further, an output terminal of the upper matching unit 27 is connected to an upper end of the upper power feed rod 28.

The power feeder 30 is made of a conductive plate such as an aluminum plate or a copper plate having a substantially cylindrical or conical shape. The power feeder 30 has a lower end continuously and entirely connected to the outer upper electrode 23 in a circumferential direction and an upper end electrically connected to a lower end of the upper power feed rod 28 through the connector 29. At the outside of the power feeder 30, the sidewall of the chamber 10 extends to a position higher than a height position of the upper electrode 22, thereby forming a cylindrical ground conductor 10a. An upper end of the cylindrical ground conductor 10a is electrically insulated from the upper power feed rod 28 by a cylindrical insulating member 69. In this configuration, a coaxial line having the power feeder 30 and the outer upper electrode 23 as a waveguide is formed by the power feeder 30, the outer upper electrode 23, and the ground conductor 10a in a load circuit viewed from the connector 29.

The inner upper electrode 24 includes an upper electrode plate 32 and an electrode holder 33. The upper electrode plate 32 is made of a semiconductor material such as silicon, silicon carbide (SiC), or the like, and has a plurality of electrode plate gas through-holes (first gas through-holes) (not shown). The electrode holder 33 is made of a conductive material such as aluminum having an alumite-treated surface and is configured to detachably hold the upper electrode plate 32. The upper electrode plate 32 is fastened to the electrode holder 33 by bolts (not shown). Head parts of the bolts are protected by an annular shield ring 53 disposed under the upper electrode plate 32.

In the upper electrode plate 32, the electrode plate gas through-holes are formed through the upper electrode plate 32. Further, a buffer space into which a processing gas to be described later is introduced is formed in the electrode holder 33. The buffer space includes two buffer spaces, i.e., a central buffer space 35 and a peripheral buffer space 36, divided by an annular partition wall member 43 made of, e.g., an O-ring. Bottoms of the buffer spaces are opened. A cooling plate (hereinafter referred to as “C/P”) 34 (intermediate member) configured to close the bottoms of the buffer spaces is disposed at a lower portion of the electrode holder 33. The C/P 34 is made of aluminum having an alumite-treated surface and has a plurality of C/P gas through-holes (second gas through-holes) (not shown). The C/P gas through-holes are formed through the C/P 34.

Further, a spacer 37 made of a semiconductor material such as silicon, silicon carbide, or the like is provided between the upper electrode plate 32 and the C/P 34. The spacer 37 is a disc-shaped member. Further, the spacer 37 has, on its surface facing the C/P 34 (hereinafter, simply referred to as “upper surface”), a plurality of concentric upper surface annular grooves and a plurality of spacer gas through-holes (third gas through-holes) opened at the bottoms of the upper surface annular grooves while being formed through the space 37.

In the inner upper electrode 24, the processing gas introduced into the buffer space from a processing gas supply source 38 to be described later is supplied to the plasma generation space S through the C/P gas through-holes of the C/P 34, a spacer gas flow path(s) of the spacer 37, and the electrode plate gas through-holes of the upper electrode plate 32. Here, the central buffer space 35, and the C/P gas through-holes, the spacer gas flow path(s) and the electrode plate gas through-holes that are disposed below the central buffer space 35 constitute a central shower head (processing gas supply path). Further, the peripheral buffer space 36, and the C/P gas through-holes, the spacer gas flow path(s) and the electrode plate gas through-holes that are disposed below the peripheral buffer space 36 constitute a peripheral shower head (process gas supply path).

Further, as shown in FIG. 1, the processing gas supply source 38 is disposed outside the chamber 10. The processing gas supply source 38 is configured to supply the processing gas to the central buffer space 35 and the peripheral buffer space 36 at a desired flow rate ratio. Specifically, the gas supply line 39 from the processing gas supply source 38 is branched into two branch lines 39a and 39b. The branch lines 39a and 39b are connected to the central buffer space 35 and the peripheral buffer space 36, respectively. The branch lines 39a and 39b are provided with flow rate control valves (FRC) 40a and 40b (flow rate controllers), respectively. The conductance of a flow path from the processing gas supply source 38 to the central buffer space 35 and the conductance of a flow path from the processing gas supply source 38 to the peripheral buffer space 36 are set to be the same. Therefore, a ratio of the flow rate of the processing gas supplied to the central buffer space 35 and the flow rate of the processing gas supplied to the peripheral buffer space 36 can be appropriately controlled by adjusting the flow rate control valves 40a and 40b. Further, a mass flow controller (MFC) 41 and an opening/closing valve 42 are disposed at the gas supply line 39.

With the above-described configuration, the plasma processing apparatus 1 is capable of adjusting the ratio of the flow rate of the processing gas introduced into the central buffer space 35 and the flow rate of the processing gas introduced into the peripheral buffer space 36 to appropriately adjust a ratio (FC/FE) between a flow rate FC of the processing gas injected from the central shower head to a flow rate FE of the processing gas injected from the peripheral shower head. Further, it is also possible to individually adjust a flow rate per unit area of the processing gas injected from the central shower head and a flow rate per unit area of the processing gas injected from the peripheral shower head. Further, two processing gas supply sources respectively corresponding to the branch pipes 39a and 39b may be disposed so that gas species or a gas mixing ratio of the processing gases injected from the central shower head and the peripheral shower head can be set independently or separately. However, the plasma processing apparatus 1 is not limited thereto and may not control the ratio FC/FR between the flow rate FC of the processing gas injected from the central shower head to the flow rate FE of the processing gas injected from the peripheral shower head.

The upper radio frequency power supply 31 is electrically connected to the electrode holder 33 of the inner upper electrode 24 through the upper matching unit 27, the upper power feed rod 28, the connector 29, and an upper power feeder 44. A variable capacitor (VC) 45 whose capacitance can be variably adjusted is disposed on a portion of the upper power feeder 44. The outer upper electrode 23 and the inner upper electrode 24 may also include a coolant chamber or a cooling jacket (not shown) so that the temperature of the electrodes can be controlled by a coolant supplied from an external chiller unit (not shown).

A gas exhaust port 46 is formed at the bottom portion of the chamber 10. An automatic pressure control valve (hereinafter, referred to as “APC valve”) 48 that is a variable butterfly valve and a turbo molecular pump (hereinafter, referred to as “TMP”) 49 are connected to the gas exhaust port 46 through a gas exhaust manifold 47. The APC valve 48 and the TMP 49 cooperate to decompress the plasma generation space S in the chamber 10 to a desired vacuum level. Further, an annular baffle plate 50 having a plurality of through-holes is disposed between the gas exhaust port 46 and the plasma generation space S to surround the susceptor 13. The baffle plate 50 serves to suppress leakage of the plasma from the plasma generation space S to the gas exhaust port 46.

In addition, at the sidewall of the chamber 10, an opening 51 for loading and unloading the wafer W is formed, and a gate valve 52 for opening and closing the opening 51 is provided. In the chamber 10, a first deposition shield 71 and a second deposition shield 72 are detachably disposed along an inner wall of the chamber 10. The first deposition shield 71 is an upper member of the deposition shield and disposed above the opening 51 of the chamber 10. The second deposition shield 72 is a lower member of the deposition shield and disposed below the baffle plate 50. When a lower portion of the first deposition shield 71 is brought into contact with an upper portion of a valve body 81 of a shutter mechanism 80 to be described later, the opening 51 is closed. The first deposition shield 71 and the second deposition shield 72 may be formed by coating an aluminum base with a ceramic such as Y₂O₃ or the like. Further, the lower portion of the first deposition shield 71 is coated with a conductive material such as stainless steel or nickel alloy so that the lower portion of the first deposition shield 71 can be electrically connected with the valve body 81 when the first deposition shield 71 is in contact with the valve body 81.

The wafer W is loaded into and unloaded from the chamber 10 by opening and closing the gate valve 52. Since, however, the gate valve 52 is disposed outside the chamber (on a transfer chamber side), a space where the opening 51 is opened toward the transfer chamber is formed at the sidewall of the chamber. Therefore, the plasma generated in the chamber 10 diffuses to the space of the opening, and the uniformity of the plasma may decrease or a sealing member of the gate valve 52 may be deteriorated by the plasma. Accordingly, by blocking the space between the first deposition shield 71 and the second deposition shield 72 with the valve body 81, the opening 51 of the chamber 10 is blocked from the plasma generation space S. Further, elevating mechanisms 82 configured to drive the valve body 81 are disposed below the second deposition shield 72, for example. The valve body 81 is vertically moved by the elevating mechanisms 82 to open and close the opening 51, i.e., the space between the first deposition shield 71 and the second deposition shield 72. The valve body 81 and the elevating mechanisms 82 may be collectively referred to as a shutter mechanism 80.

Further, in the plasma processing apparatus 1, a lower radio frequency power supply (first radio frequency power supply) 59 is electrically connected to the susceptor 13 serving as the lower electrode through a lower matching unit 58. The lower matching unit 58 is used for matching a load impedance with an internal impedance (or output impedance) of the lower radio frequency power supply 59. The lower matching unit 58 can control the load impedance and the internal impedance of the lower radio frequency power supply 59 to be apparently matched with each other when plasma is generated in the plasma generation space S of the chamber 10. Further, an additional lower radio frequency power supply (second radio frequency power supply) may be connected to the lower electrode.

Further, in the plasma processing apparatus 1, a low pass filter (LFP) 61 is electrically connected to the inner upper electrode 24. The LPF 61 is configured to suppress the radio frequency power from the upper radio frequency power supply 31 from flowing to the ground while allowing the radio frequency power from the lower radio frequency power supply 59 to flow to the ground. The LPF 61 preferably includes an LR filter or an LC filter. Since, however, a sufficiently large reactance can be applied to the radio frequency power from the upper radio frequency power supply 31 even with a single conducting wire, it may be possible to set up a configuration where the single conducting wire, instead of the LR filter or the LC filter, is electrically connected to the inner upper electrode 24. Further, a high pass filter (HPF) 62 that is configured to allow the radio frequency power from the upper radio frequency power supply 31 to flow to the ground is electrically connected to the susceptor 13.

In order to perform etching in the plasma processing apparatus 1, first, the gate valve 52 and the valve body 81 are opened, and the wafer W to be processed is loaded into the chamber 10 and placed on the susceptor 13. Then, a processing gas, such as a mixture gas of C₄F₈ gas and argon (Ar) gas, is introduced from the processing gas supply source 38 into the central buffer space 35 and the peripheral buffer space 36 at predetermined flow rates with a predetermined flow rate ratio. Further, a pressure of the plasma generation space S in the chamber 10 is set to a value suitable for etching, e.g., any value within a range of several mTorr to 1 Torr, by the APC valve 48 and the TMP 49.

Further, a radio frequency power for plasma generation is applied from the upper radio frequency power supply 31 to the upper electrode 22 (the outer upper electrode 23 and the inner upper electrode 24) at a predetermined power level, and a radio frequency power for bias is applied from the lower radio frequency power supply 59 to the lower electrode of the susceptor 13 at a predetermined power level. Further, a DC voltage is applied from the DC power supply 16 to the electrode plate 15 of the electrostatic chuck 14 to attract and hold the wafer W on the susceptor 13.

Plasma is generated in the plasma generation space S by the processing gas injected from the shower head, and a surface to be processed of the wafer W is physically or chemically etched by radicals and ions thus generated. In the plasma processing apparatus 1, high-density plasma is obtained in a desired dissociation state by applying a radio frequency power of a high frequency (at which ions cannot move) to the upper electrode 22. Further, the high-density plasma can be generated even under a lower pressure condition.

In the upper electrode 22, the outer upper electrode 23 functions as a main radio frequency electrode for plasma generation and the inner upper electrode 24 functions as a secondary radio frequency electrode for plasma generation. An intensity ratio of the electric fields applied to electrons directly below the upper electrode 22 can be controlled by the upper radio frequency power supply 31 and the lower radio frequency power supply 59. Therefore, a spatial distribution of ion density can be controlled in a radial direction, and spatial characteristics of reactive ion etching can be controlled precisely as required.

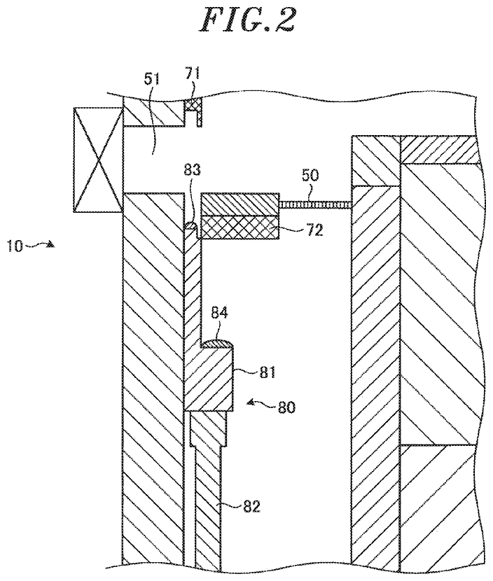

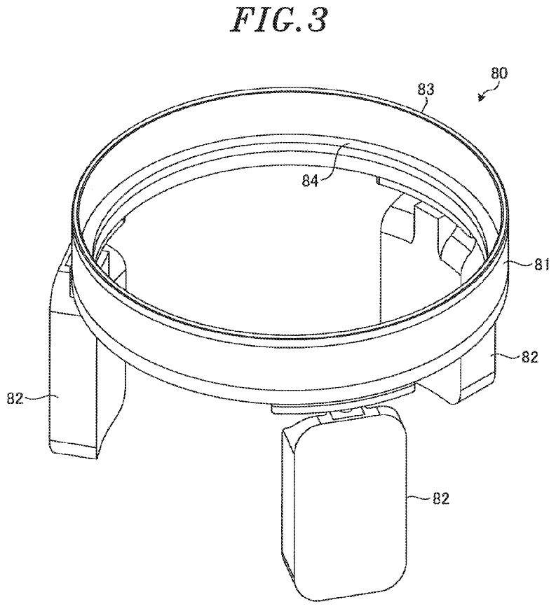

(Specific configuration of the shutter mechanism 80) FIG. 2 is a partially enlarged view showing an example of a cross section of the shutter mechanism in the present embodiment. FIG. 3 shows an example of an external appearance of the shutter mechanism in the present embodiment. As shown in FIGS. 2 and 3, the shutter mechanism 80 includes the valve body 81 having a circumferential length of at least half of the inner circumference of the chamber 10, and two or more elevating mechanisms 82 for vertically moving the valve body 81. As shown in FIG. 3, an annular valve body extending along the inner circumference of the chamber 10 can be used as the valve body 81. The valve body 81 has a conductive member 83 to be in contact with the first deposition shield 71 when the opening 51 is closed, and a conductive member 84 to be in contact with the second deposition shield 72 when the opening 51 is closed.

The valve body 81 is made of, e.g., an aluminum material, and has a substantially L-shaped cross section. The surface of the valve body 81 is coated with, e.g., Y₂O₃ or the like. The conductive member 83 is disposed at an upper end of the valve body 81. The conductive member 84 is disposed at a stepped portion of the valve body 81. Each of the conductive members 83 and 84 is a conductive elastic member, which is also referred to as a conductance band or a spiral. Further, each of the conductive members 83 and 84 may be made of, e.g., stainless steel, nickel alloy, or the like. Each of the conductive members 83 and 84 is formed by winding a band-shaped member in a spiral shape, for example. Alternatively, a U-shaped jacket with an obliquely wound coil spring installed may be used as each of the conductive members 83 and 84. In other words, the conductive members 83 and 84 are pressed when the valve body 81 is brought into contact with the first deposition shield 71 and the second deposition shield 72.

Each elevating mechanism 82 has a rod. The rod is fixedly connected to a lower portion of the valve body 81 by a screw or the like. The elevating mechanism 82 vertically moves the rod using, e.g., an air cylinder or a motor. In the case of using the air cylinder, it is controlled such that dry air can be supplied to the respective elevating mechanisms 82 at the same flow rate. In the example of FIG. 3, three elevating mechanisms 82 are arranged at equal intervals of 120 degrees. By vertically moving the elevating mechanisms 82 at the same timing and at the same speed, the valve body 81 can be vertically moved without bending or tilting. In another example, when the valve body 81 has a semicircular shape along the inner circumference of the chamber 10, the valve body 81 can be vertically moved by the elevating mechanisms 82 disposed at both ends of the valve body 81.

In the shutter mechanism 80, the opening 51 is closed when the valve body 81 is pushed upward by the elevating mechanisms 82, and the opening 51 is opened when the valve body 81 is pulled downward by the elevating mechanisms 82. In a state where the opening 51 is closed by the valve body 81, the conductive members 83 and 84 disposed at the upper portion and the lower portion of the valve body 81 are brought into contact with the first deposition shield 71 and the second deposition shield 72, respectively, so that the valve body 81 is electrically connected to the first deposition shield 71 and the second deposition shield 72 through the conductive members 83 and 84. The first deposition shield 71 and the second deposition shield 72 are in contact with the chamber 10 that is grounded. Therefore, the valve body 81 is grounded through the first deposition shield 71 and the second deposition shield 72 in the state where the opening 51 is closed.

Further, in the shutter mechanism 80, the valve body 81 corresponds to a part of a conventional deposition shield. In other words, the valve body 81 corresponds to a part of the conventional deposition shield assuming that the conventional deposition shield is divided into multiple parts. Since the conventional deposition shield is heavy, it is difficult to perform the maintenance work. However, in the present embodiment, the deposition shield is divided into the first deposition shield 71, the second deposition shield 72, and the valve body 81, so that it is easy to perform the maintenance work.

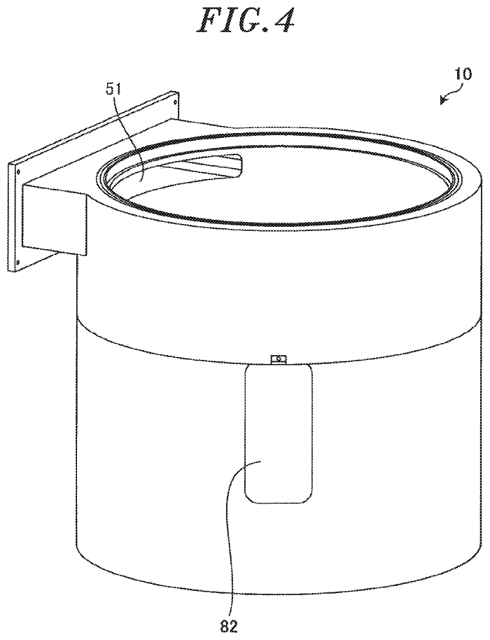

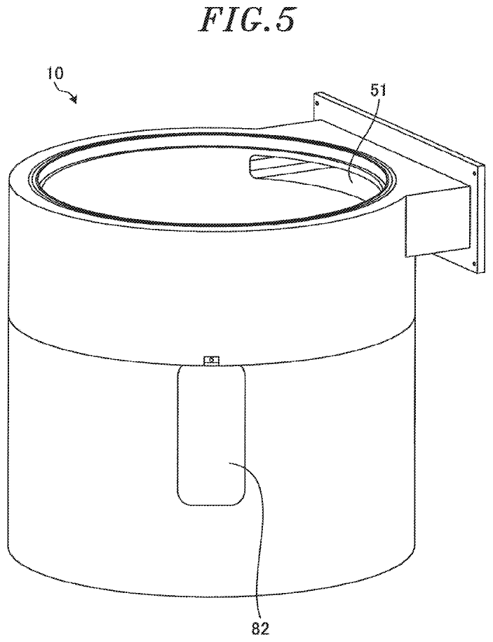

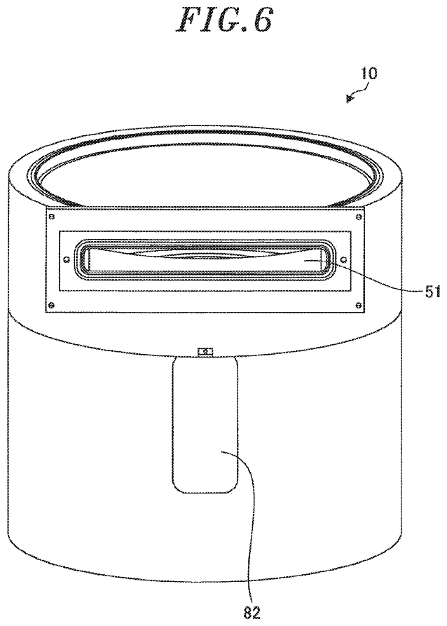

(External appearance of the chamber 10) FIGS. 4 to 6 show an example of the external appearance of the chamber in the present embodiment. In FIGS. 4 to 6, the susceptor 13, the upper electrode 22, the power feeder 30, the valve body 81 and the like are omitted for the sake of convenience in description. As shown in FIGS. 4 to 6, three elevating mechanisms 82 are arranged at equal intervals of 120 degrees in the chamber 10. The opening 51 has a width that allows not only the wafer W but also the edge ring 17 and the cover ring 54 to be transferred. The gate valve 52 can be connected to the outer side of the opening 51. The opening 51 is closed by the upward movement of the annular (ring-shape) valve body 81.

As described above, in accordance with the present embodiment, the shutter mechanism 80 for opening and closing the opening 51 of the cylindrical chamber 10 of the substrate processing apparatus (plasma processing apparatus 1) includes the valve body 81 and the elevating mechanisms 82. The valve body 81 has a circumferential length of at least half of the inner circumference of the chamber 10. The elevating mechanisms 82 includes two or more elevating mechanisms connected to the lower portion of the valve body 81 to vertically move the valve body 81. Accordingly, the opening 51 can be enlarged, and the valve body 81 can be pressed against the first deposition shield 71 with a uniform force. Further, it is possible to prevent non-uniform conduction between the valve body 81 and the first deposition shield 71. In addition, a load of each elevating mechanism 82 can be reduced. In other words, the elevating mechanisms 82 can be scaled down in size.

Further, in accordance with the present embodiment, the valve body 81 has an annular shape, so that the valve body 81 can be pressed against the first deposition shield 71 with a uniform force without tilting.

Further, in accordance with the present embodiment, three or more elevating mechanisms 82 are provided, so that the valve body 81 can be pressed against the first deposition shield 71 with a uniform force without tilting. Further, in accordance with the present embodiment, the elevating mechanisms 82 are arranged at equal intervals, so that the valve body 81 can be pressed against the first deposition shield 71 with a uniform force without tilting.

Further, in accordance with the present embodiment, the valve body 81 has the conductive member 83 on a conductive surface thereof to be in contact with the upper member (first deposition shield 71) disposed along the upper inner wall of the chamber 10. Accordingly, it is possible to prevent non-uniform conduction between the valve body 81 and the first deposition shield 71.

The presently disclosed embodiments are considered in all respects to be illustrative and not restrictive. The above-described embodiments can be embodied in various forms. Further, the above-described embodiments may be omitted, replaced, or changed in various forms without departing from the scope of the appended claims and the gist thereof.

Further, in the above-described embodiment, the plasma processing apparatus 1 is described as an example of the substrate processing apparatus. However, the present disclosure is not limited thereto and may be applied to, e.g., a substrate processing apparatus for performing processing such as atomic layer deposition (ALD) by alternately supplying a plurality of processing gases without using plasma.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made departing from the spirit of the disclosures. The accompanying claims and their equivalents are intended to cover such forms or modifications as would fall within the scope and spirit of the disclosures.

1. A shutter mechanism for opening and closing an opening of a cylindrical chamber of a substrate processing apparatus, the shutter mechanism comprising:
a valve body having a circumferential length of at least half of an inner circumference of the chamber; and
two or more elevating mechanisms connected to a lower portion of the valve body and configured to vertically move the valve body.

2. The shutter mechanism of claim 1, wherein the valve body has an annular shape.

3. The shutter mechanism of claim 1, wherein the two or more elevating mechanisms include three or more elevating mechanisms.

4. The shutter mechanism of claim 2, wherein the two or more elevating mechanisms include three or more elevating mechanisms.

5. The shutter mechanism of claim 1, wherein the elevating mechanisms are arranged at equal intervals.

6. The shutter mechanism of claim 2, wherein the elevating mechanisms are arranged at equal intervals.

7. The shutter mechanism of claim 3, wherein the elevating mechanisms are arranged at equal intervals.

8. The shutter mechanism of claim 1, wherein the valve body has a conductive member on a conductive surface thereof to be in contact with an upper member disposed along an upper inner wall of the chamber.

9. The shutter mechanism of claim 2, wherein the valve body has a conductive member on a conductive surface thereof to be in contact with an upper member disposed along an upper inner wall of the chamber.

10. The shutter mechanism of claim 3, wherein the valve body has a conductive member on a conductive surface thereof to be in contact with an upper member disposed along an upper inner wall of the chamber.

11. The shutter mechanism of claim 5, wherein the valve body has a conductive member on a conductive surface thereof to be in contact with an upper member disposed along an upper inner wall of the chamber.

12. A substrate processing apparatus comprising:
a cylindrical chamber having an opening through which a target substrate is loaded and unloaded; and
a shutter mechanism configured to open and close the opening,
wherein the shutter mechanism includes:
a valve body having a circumferential length of at least half of an inner circumference of the chamber; and
two or more elevating mechanisms that are connected to a lower portion of the valve body and configured to vertically move the valve body.
